(19) United States
(12) Patent Application Publication
(10) Pub. No.: US 2025/0261504 A1
(43) Pub. Date: Aug. 14, 2025

(54) ORGANIC LIGHT-EMITTING ELEMENT AND DISPLAY DEVICE INCLUDING THE SAME

(71) Applicants: Wuhan Tianma Microelectronics Co., Ltd. Shanghai Branch, Shanghai (CN); Wuhan Tianma Microelectronics Co, Ltd., Wuhan (CN)

(72) Inventors: Hedan WANG, Shanghai (CN); Yupei ZHANG, Shanghai (CN); Ruiming DU, Shanghai (CN); Yuanyuan LIU, Shanghai (CN); Yu ZHANG, Shanghai (CN); Zhi HUANG, Shanghai (CN)

(73) Assignees: Wuhan Tianma Microelectronics Co., Ltd. Shanghai Branch, Shanghai (CN); Wuhan Tianma Microelectronics Co., Ltd., Wuhan (CN)

(21) Appl. No.: 19/098,311

(22) Filed: Apr. 2, 2025

(30) Foreign Application Priority Data
Jul. 31, 2024 (CN) 202411047499.1

(51) Int. Cl. H10K 50/19; H10K 50/12; H10K 50/13; H10K 101/30

(52) U.S. Cl. CPC H10K 50/19; H10K 50/12; H10K 50/131; H10K 2101/30

(57) ABSTRACT

Provided are an organic light-emitting element and a display device including the same. The organic light-emitting element includes an anode, a cathode and at least two light-emitting units disposed between the anode and the cathode, where each of the at least two light-emitting units independently includes a light-emitting layer. At least one light-emitting layer includes a first light-emitting sublayer, a second light-emitting sublayer and a spacer layer disposed between the first light-emitting sublayer and the second light-emitting sublayer. A mass percentage content of a first doped material in the first light-emitting sublayer>a mass percentage content of a third doped material in the spacer layer, and a mass percentage content of a second doped material in the second light-emitting sublayer>the mass percentage content of the third doped material in the spacer layer.

### CROSS-REFERENCE TO RELATED APPLICATIONS

This application claims priority to Chinese Patent Application No. 202411047499.1, filed on Jul. 31, 2024, the contents of which are incorporated herein in its entirety by reference.

### TECHNICAL FIELD

The present disclosure belongs to the field of display technology and, in particular, relates to an organic light-emitting element and a display device including the same.

### BACKGROUND

An organic light-emitting diode (OLED) is a new generation of display technology that has been popular in recent years and has a very promising development prospect. The OLED has the advantages of self-luminescence, ultra-lightness and ultra-thinness, a wide viewing angle, a fast response speed, high luminescence efficiency and brightness, a wide operating temperature range, a simple manufacturing process, low power consumption, and flexibility. At present, the OLED is widely used in multiple fields such as flat-panel display, flexible display, in-vehicle display and solid-state lighting.

With the continuous development of OLED technology, it is gradually discovered that to obtain high brightness in a single-layer OLED element, a heat surge is caused due to an excessive drive current, resulting in a decrease in the performance and working lifetime of the element. Therefore, achieving high brightness and high efficiency at a relatively low current density, and improving the working lifetime of the element at the same time, are key factors for achieving OLED industrialization. The concept of tandem OLED, first proposed by Professor Junji Kido of Yamagata University of Japan in 2003, refers to at least two single-layer OLED units connected in series by the charge generation layer (CGL), thereby a higher brightness and current efficiency can be obtained. Moreover, when measurement is performed at the same current density, a tandem OLED and an OLED unit have the same aging properties. However, since the tandem OLED has a large initial brightness, when the initial brightness of the tandem OLED element and the single-layer OLED are converted into the same initial brightness, the lifetime of the tandem OLED element is apparently longer than that of the single-layer OLED.

Although the tandem OLED element is improved in luminescence performance and working lifetime compared with the single-layer OLED element, as the application scope of the element expands and the requirement of users for display performance increases, the tandem OLED element still has apparent disadvantages in lifetime and luminescence efficiency and has a very large room for performance improvement. Therefore, a tandem OLED element with higher performance needs to be developed in the art urgently.

### SUMMARY

To improve the luminescence efficiency and lifetime of a tandem OLED and develop a tandem OLED element with higher luminescence performance, a first object of the present disclosure is to provide an organic light-emitting element. The organic light-emitting element includes an anode, a cathode and at least two light-emitting units disposed between the anode and the cathode, where each of the at least two light-emitting units independently includes a light-emitting layer.

At least one light-emitting layer includes a first light-emitting sublayer, a second light-emitting sublayer and a spacer layer disposed between the first light-emitting sublayer and the second light-emitting sublayer. The first light-emitting sublayer includes a first host material and a first doped material, the second light-emitting sublayer includes a second host material and a second doped material, and the spacer layer includes a third host material and an optional third doped material.

A mass percentage content of the first doped material in the first light-emitting sublayer>a mass percentage content of the third doped material in the spacer layer, and a mass percentage content of the second doped material in the second light-emitting sublayer>the mass percentage content of the third doped material in the spacer layer.

In the organic light-emitting element provided in the present disclosure, at least one light-emitting layer adopts the particular design of three-layer structure. The contents of the doped materials in the first light-emitting sublayer and the second light-emitting sublayer that are located on two sides are high, and the content of the doped material in the intermediate spacer layer is low so that a particular concentration gradient of the doped materials is formed in the light-emitting layer, exciton quenching can be effectively reduced, regions for exciton formation and recombination can be increased, efficiency roll-off can be inhibited, thereby the organic light-emitting element can have higher luminescence efficiency and a longer working lifetime.

A second object of the present disclosure is to provide a display device. The display device includes the organic light-emitting element described in the first object.

Compared with the related art, the present disclosure has the beneficial effects described below.

In the organic light-emitting element provided in the present disclosure, at least one light-emitting layer includes the first light-emitting sublayer, the spacer layer and the second light-emitting sublayer that are disposed in sequence. The content of the doped material in the intermediate spacer layer is lower than the contents of the doped materials in the first light-emitting sublayer and the second light-emitting sublayer that are located on the two sides so that the particular concentration gradient of the doped materials is formed in the light-emitting layer, the exciton quenching can be effectively reduced, regions for the exciton formation and recombination can be increased, the efficiency roll-off can be avoided, the organic light-emitting element can have more excellent luminescence efficiency and stability, the working lifetime of the element can be significantly prolonged, the overall luminescence performance can be improved and the organic light-emitting element can fully meets application requirements of the tandem OLED element in a high-performance display device and an electronic device.

### BRIEF DESCRIPTION OF DRAWINGS

FIG. 1 is a structure diagram of a light-emitting layer in an organic light-emitting element provided in an embodiment of the present disclosure.

FIG. 2 is a structure diagram of an organic light-emitting element provided in an embodiment of the present disclosure.

### DETAILED DESCRIPTION

Technical solutions of the present disclosure are further described below through specific examples. It is to be understood by those skilled in the art that the examples described below are used for a better understanding of the present disclosure and are not to be construed as specific limitations to the present disclosure.

In the present disclosure, a feature defined as a “first” feature, a “second” feature or a “third” feature may explicitly or implicitly include one or more of such features to distinguish and describe features regardless of order or weight. In the description of the present disclosure, unless otherwise noted, the phrase “a plurality of” means two or more.

In the present disclosure, it is to be understood that orientations or position relations indicated by terms such as “upper”, “lower”, “inner”, “outer”, “vertical”, and “horizontal” are orientations or position relations based on the drawings. These orientations or position relations are intended only to facilitate the description of the present disclosure and simplify the description and not to indicate or imply that a device or element referred to must have such specific orientations or must be configured or operated in such specific orientations. Thus, these orientations or position relations are not to be construed as limiting the present disclosure.

In the present disclosure, unless otherwise expressly specified and limited, the terms “connected to each other”, “connected”, “installed” or “fixed” should be construed in a broad sense, for example, as fixedly connected, detachably connected, or integrated; mechanically connected or electrically connected; directly connected to each other or indirectly connected to each other via an intermediary; or internally connected between two elements or interactional relations between two elements. For those of ordinary skill in the art, the above terms can be construed according to specific circumstances in the present disclosure.

In the present disclosure, it is found through studies that a tandem organic electroluminescent element (tandem OLED) includes at least two light-emitting units that are connected in series, and adjacent light-emitting units are connected to each other by a CGL. Compared with a single-layer OLED, the tandem OLED has relatively high element efficiency and a relatively long lifetime. However, as the application scope of the element expands and the requirement of users for display performance improves, the existing tandem OLED has the problems of insufficient luminescence efficiency and a relatively short lifetime. Moreover, the CGL causes voltage drop, further resulting in a decrease in the efficiency and lifetime of the stacked element.

To improve the luminescence efficiency and lifetime of the tandem OLED and obtain more excellent luminescence performance, an embodiment of the present disclosure provides an organic light-emitting element. The organic light-emitting element includes an anode, a cathode and at least two light-emitting units disposed between the anode and the cathode, where each of the at least two light-emitting units independently includes a light-emitting layer.

At least one light-emitting layer includes a first light-emitting sublayer, a second light-emitting sublayer and a spacer layer disposed between the first light-emitting sublayer and the second light-emitting sublayer. The first light-emitting sublayer includes a first host material and a first doped material, the second light-emitting sublayer includes a second host material and a second doped material, and the spacer layer includes a third host material and an optional third doped material.

A mass percentage content of the first doped material in the first light-emitting sublayer>a mass percentage content of the third doped material in the spacer layer, and a mass percentage content of the second doped material in the second light-emitting sublayer>the mass percentage content of the third doped material in the spacer layer.

In the present disclosure, at least one light-emitting layer has the particular three-layer structure. The contents of the doped materials in the first light-emitting sublayer and the second light-emitting sublayer that are located on two sides are high, and the content of the doped material in the intermediate spacer layer is low (or no doping), so that a particular concentration gradient of the doped materials is formed in the light-emitting layer, exciton quenching can be effectively reduced, efficiency roll-off can be inhibited, and regions for exciton formation and recombination can be increased, thereby improving the luminescence efficiency and stability of the organic light-emitting element, prolonging the working lifetime and giving the organic light-emitting element more excellent luminescence performance.

To make the above objects, features and effects of the present disclosure more apparent, the present disclosure is further described in detail in conjunction with the drawings. The drawings of the present disclosure are merely used as schematic diagrams and are not necessarily drawn according to actual scales.

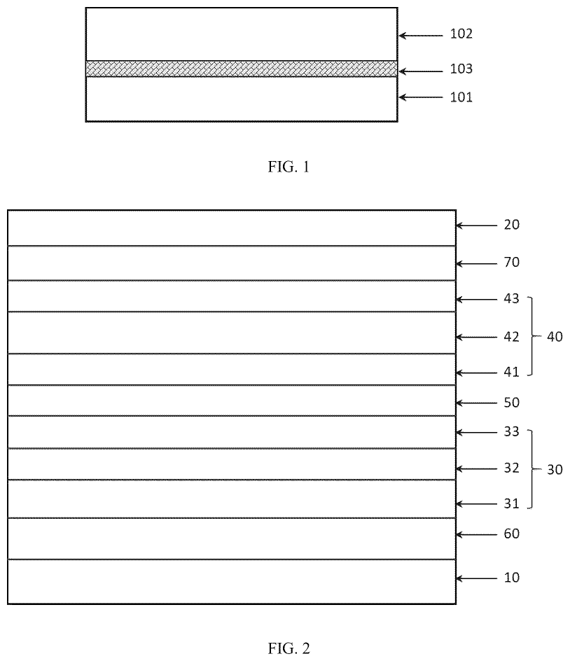

FIG. 1 is a structure diagram of a light-emitting layer in an organic light-emitting element provided in an embodiment of the present disclosure. The light-emitting layer includes a first light-emitting sublayer 101, a second light-emitting sublayer 102 and a spacer layer 103 disposed between the first light-emitting sublayer 101 and the second light-emitting sublayer 102. The first light-emitting sublayer 101 includes a first host material and a first doped material, the second light-emitting sublayer 102 includes a second host material and a second doped material, and the spacer layer 103 includes a third host material and an optional third doped material. A mass percentage content of the first doped material in the first light-emitting sublayer 101>a mass percentage content of the third doped material in the spacer layer 103, and a mass percentage content of the second doped material in the second light-emitting sublayer 102>the mass percentage content of the third doped material in the spacer layer 103.

It is to be noted that in the light-emitting layer, the first doped material, the second doped material and the optional third doped material may be the same material or different materials, and the first host material, the second host material and the third host material may be the same material or different materials. According to the consideration from the perspectives of preparation processability, material energy level, carrier transport performance and matching of photoelectric performance, the first doped material, the second doped material and the optional third doped material are the same material, and the first host material, the second host material and the third host material are the same material, so that the number of evaporation sources in a chamber does not need to be increased during the element preparation, thereby reducing a preparation cost.

In some optional embodiments of the present disclosure, the mass percentage content of the first doped material in the first light-emitting sublayer is 0.5% to 12%, which may be, for example, 1%, 2%, 3%, 4%, 5%, 6%, 7%, 8%, 9%, 10% or 11%, and specific point values between the above point values. Due to the limitation of space and the consideration of simplicity, the specific point values included in the range are not exhaustively listed in the present disclosure.

And/or the mass percentage content of the second doped material in the second light-emitting sublayer is 0.5% to 12%, which may be, for example, 1%, 2%, 3%, 4%, 5%, 6%, 7%, 8%, 9%, 10% or 11%, and specific point values between the above point values. Due to the limitation of space and the consideration of simplicity, the specific point values included in the range are not exhaustively listed in the present disclosure.

And/or the mass percentage content of the third doped material in the spacer layer is less than or equal to 3%, which may be, for example, 0, 0.1%, 0.2%, 0.5%, 0.8%, 1%, 1.2%, 1.5%, 1.8%, 2%, 2.2%, 2.5% or 2.8%, and specific point values between the above point values. Due to the limitation of space and the consideration of simplicity, the specific point values included in the range are not exhaustively listed in the present disclosure.

In the present disclosure, “doped material”, which is also referred to as “guest material”, “dye” or “light-emitting material”, receives energy from the host material and emits a corresponding optical spectrum, thereby achieving luminescence of different colors. According to the luminescence mechanism of the light-emitting layer, the luminescence may be roughly divided into fluorescent luminescence and phosphorescence luminescence that correspond to a fluorescent doping material and a phosphorescent doping material, respectively. The fluorescent doping material mainly emits light by using singlet excitons generated when electrons and holes are combined, and the phosphorescent doping material can emit light by simultaneously using both triplet excitons and singlet excitons. In the present disclosure, the contents of the doped materials in the light-emitting layers with different luminescence mechanisms are optimized and adjusted so that a particular concentration gradient of the doped materials is formed in the light-emitting layer, thereby further optimizing the photoelectric performance of the organic light-emitting element and obtaining a longer lifetime and higher efficiency.

In some optional embodiments of the present disclosure, the first doped material, the second doped material and the third doped material are phosphorescent doping materials, the mass percentage content of the first doped material (the phosphorescent doping material) in the first light-emitting sublayer is 1% to 12%, which may be, for example, 1.5%, 2%, 3%, 4%, 5%, 6%, 7%, 8%, 9%, 10% or 11%, and specific point values between the above point values. Due to the limitation of space and the consideration of simplicity, the specific point values included in the range are not exhaustively listed in the present disclosure.

And/or the mass percentage content of the second doped material (the phosphorescent doping material) in the second light-emitting sublayer is 1% to 12%, which may be, for example, 1.5%, 2%, 3%, 4%, 5%, 6%, 7%, 8%, 9%, 10% or 11%, and specific point values between the above point values. Due to the limitation of space and the consideration of simplicity, the specific point values included in the range are not exhaustively listed in the present disclosure.

And/or the mass percentage content of the third doped material (the phosphorescent doping material) in the spacer layer is less than or equal to 3%, which may be, for example, 0, 0.1%, 0.2%, 0.5%, 0.8%, 1%, 1.2%, 1.5%, 1.8%, 2%, 2.2%, 2.5% or 2.8%, and specific point values between the above point values. Due to the limitation of space and the consideration of simplicity, the specific point values included in the range are not exhaustively listed in the present disclosure.

In some optional embodiments of the present disclosure, the first doped material, the second doped material and the third doped material are fluorescent doping materials, the mass percentage content of the first doped material (the fluorescent doping material) in the first light-emitting sublayer is 0.5% to 5%, which may be, for example, 0.6%, 0.8%, 1%, 1.5%, 2%, 2.5%, 3%, 3.5%, 4% or 4.5%, and specific point values between the above point values. Due to the limitation of space and the consideration of simplicity, the specific point values included in the range are not exhaustively listed in the present disclosure.

And/or the mass percentage content of the second doped material (the fluorescent doping material) in the second light-emitting sublayer is 0.5% to 5%, which may be, for example, 0.6%, 0.8%, 1%, 1.5%, 2%, 2.5%, 3%, 3.5%, 4% or 4.5%, and specific point values between the above point values. Due to the limitation of space and the consideration of simplicity, the specific point values included in the range are not exhaustively listed in the present disclosure.

And/or the mass percentage content of the third doped material (the fluorescent doping material) in the spacer layer is less than or equal to 2%, which may be, for example, 0, 0.1%, 0.2%, 0.5%, 0.8%, 1%, 1.2%, 1.5% or 1.8%, and specific point values between the above point values. Due to the limitation of space and the consideration of simplicity, the specific point values included in the range are not exhaustively listed in the present disclosure.

In the present disclosure, for a phosphorescent light-emitting layer, the mass content of the phosphorescent doping material in the spacer layer is preferably less than or equal to 3%, and for a fluorescent light-emitting layer, the mass content of the fluorescent doping material in the spacer layer is preferably less than or equal to 2%. In this manner, a particular doping concentration gradient of high-concentration doping on two particular sides and low-concentration doping (or no doping) on the intermediate section is formed in the light-emitting layer, so that exciton quenching and efficiency roll-off are inhibited, regions for exciton formation and recombination are effectively increased and the organic light-emitting element has higher luminescence efficiency and a longer working lifetime. If the content of the doped material in the spacer layer is too high, the construction of the concentration gradient will be affected, and the improvement in the performance and lifetime of the element will not be remarkable.

In some optional embodiments of the present disclosure, thicknesses of the first light-emitting sublayer and the second light-emitting sublayer are each independently 8 nm to 30 nm, which may be, for example, 9 nm, 10 nm, 12 nm, 15 nm, 18 nm, 20 nm, 22 nm, 25 nm or 28 nm, and specific point values between the above point values. Due to the limitation of space and the consideration of simplicity, the specific point values included in the range are not exhaustively listed in the present disclosure.

And/or a thickness of the spacer layer is 1 nm to 7 nm, which may be, for example, 1.5 nm, 2 nm, 2.5 nm, 3 nm, 3.5 nm, 4 nm, 4.5 nm, 5 nm, 5.5 nm, 6 nm or 6.5 nm, and specific point values between the above point values. Due to the limitation of space and the consideration of simplicity, the specific point values included in the range are not exhaustively listed in the present disclosure, and the thickness is further preferably 1 nm to 5 nm.

In the present disclosure, the spacer layer with a low doping concentration (or no doping) is introduced into the light-emitting layer. The thickness of the spacer layer is further optimized, thereby reducing the exciton quenching and the efficiency roll-off and further improving the efficiency and lifetime of the organic light-emitting element while ensuring brightness. If the thickness of the spacer layer is too high, that is, a region of a low doping concentration (or no doping) is relatively large, the brightness of the element will be affected, and it will not be conducive to improving the luminescence efficiency and the lifetime.

In some optional embodiments of the present disclosure, the first host material, the second host material and the third host material each independently include any one or a combination of at least two of an electron-type host material, a hole-type host material, a bipolar host material and an exciplex material.

Optionally, the first host material, the second host material and the third host material are the same or different, further preferably the same. The first host material, the second host material and the third host material include, but are not limited to, any one or a combination of at least two of the following compounds: 4,4′-bis(9-carbazolyl) biphenyl (CBP), 4,4′,4″-tris(carbazol-9-yl)-triphenylamine (TCTA), 9,9′-diphenyl-9H,9′H-3,3′-bicarbazole (BCzPh), 1,3,5-tris(carbazol-9-yl)benzene (TCP), 4,4′-bis(carbazol-9-yl)-2,2′-dimethylbiphenyl (CDBP), 3′-(9H-carbazol-9-yl) biphenyl-3,5-dicarbonitrile (mCzB-2CN), 2,2′,7,7′-tetra(carbazol-9-yl)-9,9-spiro-fluorene (spiro-CBP), 4′-(9H-carbazol-9-yl) biphenyl-3,5-dicarbonitrile (PCzB-2CN), 3,6-bis(carbazol-9-yl)-9-(2-ethyl-hexyl)-9H-carbazole (TcZ1), bis(2-diphenylphosphine oxide)diphenyl ether (DPEPO), 2,7-bis(9H-carbazol-9-yl)-9,9-dimethylfluorene (DMFL-CBP), 1,3-bis(N-carbazolyl)benzene (mCP), 9-(3-(9H-carbazol-9-yl)phenyl)-9H-carbazol-3-carbonitrile (mCP-CN), 3,3′-bis(N-carbazolyl)-1,1′-biphenyl(mCBP), 9-(3-(9H-carbazol-9-yl)phenyl)-3-(diphenylphosphoryl)-9H-carbazole (mCPPO1), 9,9-spirobifluoren-2-yl-diphenylphosphine oxide (SPPO1), 3,5-bis(9H-carbazol-9-yl) biphenyl(Ph-mCP) and 2-(10-naphthyl-anthracen-9-yl)dibenzofuran.

In some optional embodiments of the present disclosure, each of the at least two light-emitting units independently includes a hole transport zone and an electron transport zone, and the light-emitting layer is disposed between the hole transport zone and the electron transport zone.

In some optional embodiments of the present disclosure, a CGL is disposed between any two adjacent light-emitting units.

In some optional embodiments of the present disclosure, a hole injection layer is further disposed between the anode and the light-emitting unit adjacent to the anode.

In some optional embodiments of the present disclosure, an electron injection layer is further disposed between the cathode and the light-emitting unit adjacent to the cathode.

In some optional embodiments of the present disclosure, a structure diagram of the organic light-emitting element is shown in FIG. 2. The organic light-emitting element includes an anode 10, a cathode 20, and a first light-emitting unit 30 and a second light-emitting unit 40 that are disposed between the anode 10 and the cathode 20. A CGL 50 is disposed between the first light-emitting unit 30 and the second light-emitting unit 40. The first light-emitting unit 30 includes a first hole transport zone 31, a first electron transport zone 33 and a first light-emitting layer 32 disposed between the first hole transport zone 31 and the first electron transport zone 33. The second light-emitting unit 40 includes a second hole transport zone 41, a second electron transport zone 43 and a second light-emitting layer 42 disposed between the second hole transport zone 41 and the second electron transport zone 43. A hole injection layer 60 is disposed between the anode 10 and the first light-emitting unit 30, and an electron injection layer 70 is disposed between the cathode 20 and the second light-emitting unit 40. At least one of the first light-emitting layer 32 and the second light-emitting layer 42 has the structural design of the first light-emitting sublayer, the spacer layer and the second light-emitting sublayer as aforementioned, that is, at least one of the first light-emitting layer 32 and the second light-emitting layer 42 has the structure shown in FIG. 1.

In some optional embodiments of the present disclosure, the hole transport zone includes a hole transport layer (HTL) and an optional electron blocking layer (EBL), and/or the electron transport zone includes an electron transport layer (ETL) and an optional hole blocking layer (HBL), and/or a hole injection layer (HIL) is further disposed between the anode and the light-emitting unit adjacent to the anode, and/or an electron injection layer (EIL) is further disposed between the cathode and the light-emitting unit adjacent to the cathode, and/or a CGL is disposed between any two adjacent light-emitting units.

Optionally, a material of the anode may be any one or a combination of at least two of a metal, a metal oxide and a conductive polymer, where the metal includes copper, gold, silver, iron, chromium, nickel, manganese, palladium, platinum and the like as well as alloys thereof, the metal oxide includes indium tin oxide (ITO), indium zinc oxide (IZO), zinc oxide, indium gallium zinc oxide (IGZO) and the like, and the conductive polymer includes polyaniline, polypyrrole, poly(3-methylthiophene) and the like. In addition to the above materials that facilitate hole injection and combinations thereof, the material of the anode further includes known materials suitable for use as the anode.

Optionally, a material of the cathode may be a metal or a multilayer metal material, where the metal includes aluminum, magnesium, silver, indium, tin, titanium and the like as well as alloys thereof, and the multilayer metal material includes LiF/Al, LiO₂/Al, BaF₂/Al and the like. In addition to the above materials that facilitate electron injection and combinations thereof, the material of the cathode further includes known materials suitable for use as the cathode.

It is to be noted that materials of the HIL, the hole transport zone (the HTL and the optional EBL), the EIL and the electron transport zone (the ETL and the optional HBL) are not specially limited in the present disclosure. A hole injection material, a hole transport material, an electron blocking material, an electron injection material, an electron transporting material and a hole blocking material that are known in the art may all be applicable to the present disclosure.

Optionally, the materials of the HIL and the hole transport zone (the HTL and the optional EBL) include, but are not limited to, any one or a combination of at least two of the following compounds: 4,4′,4″-tris(3-methylphenylamino)triphenylamine (MTDATA), 4,4′,4″-tris(N,N-diphenyl-amino)triphenylamine (NATA), 4,4′,4″-tris(N-(naphth-1-yl)-N-phenyl-amino)triphenylamine (1T-NATA), 4,4′,4″-tris(N-(naphth-2-yl)-N-phenyl-amino)triphenylamine (2TNATA), copper phthalocyanine (CuPc), 1,3,5-tris(4-(diphenylamino)phenyl)benzene (TDAPB), 2,2′-dimethyl-N,N′-bis-1-naphthyl-N,N′-diphenyl(1,1′-biphenyl)-4,4′-diamine (α-NPD), 4,4′,4″-tris(carbazol-9-yl)-triphenylamine (TCTA), 1,3-bis(N-carbazolyl)benzene (mCP), 4,4′-bis(9-carbazolyl) biphenyl (CBP), 3,3′-bis(N-carbazolyl)-1,1′-biphenyl(mCBP), 2,3,6,7,10,11-hexacyano-1,4,5,8,9,12-hexaazatriphenylene (HATCN), 4,4′-cyclohexylidenebis(N,N-bis(4-methylphenyl) aniline) (TAPC), N,N′-diphenyl-N,N′-(1-naphthyl)-1,1′-biphenyl-4,4′-diamine (α-NPB), N,N′-bis(naphth-2-yl)-N,N′-di(phenyl) biphenyl-4,4′-diamine (NPB), poly(3,4-ethylenedioxythiophene):polystyrene sulfonate (PEDOT:PSS), 2,3,5,6-tetrofluoro-7,7,8,8-tetracyanoquinodimethane (F4TCNQ), N-(biphenyl-4-yl)-9,9-dimethyl-N-(4-(9-phenyl-9H-carbazol-3-yl)phenyl)-9H-fluoren-2-amine-polyvinylcarbazole (PVK), 4,4′-bis(N-carbazolyl)-1,1′-biphenyl (CBP), poly(N,N′-bis(4-butylphenyl)-N,N′-bis(phenyl)-benzidine)(poly-TPD), poly((9,9-dioctylfluorenyl-2,7-diyl)-co-(4,4′-(N-(4-sec-butylphenyl)diphenylamine))) (TFB), 1,1-bis(4-(N,N′-bis(p-tolyl)amino)phenyl)cyclohexane (TAPC), 3,5-bis(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl) biphenyl-4-amine, N-((1,1′-biphenyl)-4-yl)-9,9-dimethyl-N-(4-(9-phenyl-9H-carbazol-3-yl)phenyl)-9H-fluoren-2-a mine, N4,N4,N4′,N4′-tetra((1,1′-biphenyl)-4-yl)-((1,1′-biphenyl)-4,4′-diamine) 9-phenyl-3,9-bicarbazol e (CCP) and molybdenum trioxide (MoO₃).

Optionally, the materials of the EIL and the electron transport zone (the ETL and the optional HBL) include, but are not limited to, any one or a combination of at least two of the following compounds: 2,8-bis(diphenylphosphinyl)dibenzothiophene (PPT), diphenyl(4-(triphenylsilyl)phenyl)phosphine oxide (TSPO1), 1,3,5-tris(1-phenyl-1H-benzimidazol-2-yl)benzene (TPBi), 2,8-bis(diphenylphosphinyl)dibenzofuran (PPF), bis(2-diphenylphosphine oxide)diphenyl ether (DPEPO), lithium fluoride (LiF), 4,6-bis(3,5-bis(3-pyridine) yl-phenyl)-2-methylpyrimidine (B3PYMPM), 4,7-diphenyl-1,10-phenanthroline (Bphen), 1,3,5-tris((3-pyridyl)-3-phenyl)benzene (TmPyBP), 1,3,5-tris(para-pyridin-3-yl-phenyl)benzene (TpPyPB), tris(2,4,6-trimethyl-3-(3-pyridyl)phenyl) borine (3TPYMB), 1,3-bis(3,5-bipyridin-3-yl-phenyl)benzene (B3PYPB), 1,3-bis(3,5-bis(pyridin-3-yl)phenyl)benzene (BMPYPHB), 2,4,6-tris(biphenyl-3-yl)-1,3,5-triazine (T2T), diphenylbis(4-(pyridin-3-yl)phenyl) silane (DPPS), cesium carbonate (Cs₂CO₃), bis(2-methyl-8-hydroquinolinolato-N1,08)-(1,1′-biphenyl-4-hydroxyl)aluminium (BAlq), 8-hydroxyquinolinolato-lithium (LiQ), tris(8-hydroxyquinolinato)aluminium (Alq₃), 2-biphenyl-4-yl-5-(4-tert-butylphenyl)-1,3,4-diazole (PBD), spiro-PBD, 2,9-bis(naphth-2-yl)-4,7-diphenyl-1,10-phenanthroline (NBphen), 2,9-dimethyl-4,7-diphenyl-1,10-phenanthroline (BCP), 3-(4-biphenyl)-4-phenyl-5-tert-butylphenyl-1,2,4-triazole (TAZ), 4-(naphth-1-yl)-3,5-diphenyl-4H-1,2,4-triazole (NTAZ), 2,4,6-tris(3′-(pyridin-3-yl) biphenyl-3-yl)-1,3,5-triazine (TmPPPyTz), poly(9,9-bis(3′-(N,N-dimethyl)-N-ethylammoinium-propyl-2,7-fluorene)-alt-2,7-(9,9-dioctylfluo rene)) (PFNBr), tris(phenylquinoxaline)(TPQ) and 2-(4-(9,10-bis-2-naphth-2-yl-2-anthracen-2-yl)phenyl)-1-phenyl-1H-benzimidazole (ZADN).

In some optional embodiments of the present disclosure, the CGL includes a p-type layer, an n-type layer and a barrier layer disposed between the p-type layer and the n-type layer.

In some optional embodiments of the present disclosure, the p-type layer includes a p-type host material and a p-type dopant, the n-type layer includes an n-type host material and an n-type dopant, and the barrier layer includes a p-type host material and/or an n-type host material.

Optionally, the p-type host material includes any one or a combination of at least two of arylamine compounds.

Optionally, the p-type dopant includes any one or a combination of at least two of the following groups: cyano, fluorine, chlorine, trifluoromethyl and trifluoromethoxy.

Optionally, the n-type host material includes any one or a combination of at least two of the following groups: pyridyl, pyrazinyl, pyrimidinyl, pyridazinyl, triazinyl, quinolyl, isoquinolyl, quinoxalinyl, quinazolinyl, benzopyridazinyl and ortho-phenanthrolinyl (phenanthrolinyl).

Optionally, the n-type dopant includes any one or a combination of at least two of an alkali metal, an alkali metal compound, a transition metal and a transition metal compound.

In some optional embodiments of the present disclosure, the n-type dopant includes any one or a combination of at least two of Li, Cs, Yb and Cs₂CO₃.

Optionally, a material of the barrier layer includes sp2-hybridized nitrogen atom groups, for example, pyridyl, pyrazinyl, pyrimidinyl, pyridazinyl, triazinyl, quinolyl, isoquinolyl, quinoxalinyl, quinazolinyl, ortho-phenanthrolinyl (phenanthrolinyl) and benzopyridazinyl. The barrier layer can effectively capture the n-type dopant in the n-type layer and limit the n-type dopant in the n-type layer (n-doped), thereby avoiding interface deterioration caused by the diffusion of the n-type dopant to the p-type layer, reducing a thickness of a depletion layer and improving the stability of the element.

In some optional embodiments of the present disclosure, the barrier layer has a lowest unoccupied molecular orbital (LUMO) energy level of 2.5-2.9 eV, which may be, for example, 2.55 eV, 2.6 eV, 2.65 eV, 2.7 eV, 2.75 eV, 2.8 eV or 2.85 eV, and specific point values between the above point values. Due to the limitation of space and the consideration of simplicity, the specific point values included in the range are not exhaustively listed in the present disclosure. The barrier layer has a highest occupied molecular orbital (HOMO) energy level of 5.5-6.0 eV, which may be, for example, 5.55 eV, 5.6 eV, 5.65 eV, 5.7 eV, 5.75 eV, 5.8 eV, 5.85 eV, 5.9 eV or 5.95 eV, and specific point values between the above point values. Due to the limitation of space and the consideration of simplicity, the specific point values included in the range are not exhaustively listed in the present disclosure.

Optionally, the HOMO energy level of the barrier layer is as close as possible to the LUMO energy level of the p-type layer (p-doped), thereby effectively reducing a potential barrier between CGLs. The mobility is about 10-4 cm²/Vs to 10-3 cm²/Vs. The CGL formed by the p-type layer can effectively generate charges, thereby improving the luminescence performance and working lifetime of the organic light-emitting element having a stacked structure.

In some optional embodiments of the present disclosure, thicknesses of the p-type layer and the n-type layer are each independently 2 nm to 30 nm, which may be, for example, 3 nm, 5 nm, 8 nm, 10 nm, 12 nm, 15 nm, 18 nm, 20 nm, 22 nm, 25 nm or 28 nm, and specific point values between the above point values. Due to the limitation of space and the consideration of simplicity, the specific point values included in the range are not exhaustively listed in the present disclosure.

And/or a thickness of the barrier layer is 0.5 nm to 2 nm, which may be, for example, 0.6 nm, 0.8 nm, 1 nm, 1.2 nm, 1.5 nm or 1.8 nm, and specific point values between the above point values. Due to the limitation of space and the consideration of simplicity, the specific point values included in the range are not exhaustively listed in the present disclosure.

In some optional embodiments of the present disclosure, each of the light-emitting units is independently selected from any one of a green light-emitting unit, a blue light-emitting unit, a red light-emitting unit or a yellow light-emitting unit.

As a green light-emitting unit, for example, a green light doping material of a (green) light-emitting layer of the green light-emitting unit includes, but is not limited to, any one or a combination of at least two of the following compounds: tris(2-phenylpyridine)iridium(III) (Ir(ppy)₃), fac-tri(2-phenylpyridine)iridium(III) (fac-Ir(ppy)₃), bis(2-phenylpyridine) (acetylacetonato)iridium(III) (Ir(ppy)₂(acac)), tris(2-(p-tolyl) pyridine)iridium(III) (Ir(mppy)₃), bis(2-(naphth-2-yl)pyridine) (acetylacetonato)iridium(III) (Ir(npy)₂(acac)) and tris(2-phenyl-3-methyl-pyridine)iridium(Ir(3mppy)₃).

As a blue light-emitting unit, for example, a blue light doping material of a (blue) light-emitting layer of the blue light-emitting unit includes, but is not limited to, any one or a combination of at least two of the following compounds: perylene, 4,4′-bis(4-(di-p-tolylamino) styryl) biphenyl (DPAVBi), 4-(di-p-tolylamino)-4,4′-((di-p-tolylamino) styryl) styrene (DPAVB), 4,4′-bis(4-(diphenylamino) styryl) biphenyl (BDAVBi), 2,7-bis(4-(diphenylamino) styryl)-9,9-spirofluorenyl (spiro-DPVBi), 1,4-bis(2-(4-(N,N-di (p-tolyl)amino)phenyl) vinyl)benzene (DSB), 1,4-bis(N,N-diphenyl)amino) styrylbenzene (DSA), 2,5,8,11-tetra-tert-butylperylene (TBPe), bis((2-hydroxyphenyl)pyrido) beryllium (Bepp₂), 9-(9-phenylcarbazol-3-yl)-10-(naphth-1-yl) anthracene (PCAN) and 1,6-bis(diphenylamine) pyrene.

As a red light-emitting unit, for example, a red light doping material of a (red) light-emitting layer of the red light-emitting unit includes, but is not limited to, any one or a combination of at least two of the following compounds: tris(1-phenylisoquinoline)iridium(III) (Ir(piq)₃), (bis(2-(4,6-dimethyl)phenylquinoline)) (2,2,6,6-tetramethylheptan-3,5-dionate)iridium(III), bis(2-(4-n-hexylphenyl) quinoline) (acetylacetonato)iridium(III) (Hex-Ir(phq)₂(acac)), tris(2-(4-n-hexylphenyl) quinoline)iridium(III) (Hex-Ir(phq)₃), tris(2-phenyl-4-methylquinoline)iridium(III) (Ir(Mphq)₃), bis(2-phenylquinoline) (2,2,6,6-tetramethylheptan-3,5-dionate)iridium(III) (Ir(dpm)PQ₂), bis(phenylisoquinoline)-(2,2,6,6-tetramethylheptan-3,5-dionate)iridium(III) (Ir(dpm)(piq)₂), bis((4-n-hexylphenyl) isoquinoline) (acetylacetonato)iridium(III) (Hex-Ir(piq)₂(acac)), tris(2-(4-n-hexylphenyl) quinoline)iridium(III) (Hex-Ir(piq)₃), tris(2-(3-methylphenyl)-7-methyl-quinolyl)iridium(Ir(dmpq)₃), bis(2-(2-methylphenyl)-7-methyl-quinolyl) (acetylacetonato)iridium(III) (Ir(dmpq)₂(acac)), bis(2-(3,5-dimethylphenyl)-4-methyl-quinoline) (acetylacetonato)iridium(III) (Ir(mphmq)₂(acac)) and tris(dibenzoylmethane) mono (1,10-phenanthroline) europium(III) (Eu(dbm)₃(phen)).

It is to be noted that the number of light-emitting units in the organic light-emitting element is denoted as n, and n is more than or equal to 2. For example, n may be 2, 3, 4, 5 or 6. Each light-emitting unit includes a light-emitting layer, and all light-emitting units/light-emitting layers are the same or different. At least one (for example, one, two or three) of the light-emitting layers has the structural design of the first light-emitting sublayer, the spacer layer and the second light-emitting sublayer as aforementioned. Since the lifetime of white light consists of R/G/B in a display device and the lifetime of green light accounts for the highest proportion that is 80% or more, to improve the lifetime of the white light, it is particularly important to improve the lifetime of the green light. Based on this, the structural design (as shown in FIG. 1) of the first light-emitting sublayer, the spacer layer and the second light-emitting sublayer as aforementioned is performed on the green light-emitting unit/green light-emitting layer so that a particular doping concentration gradient is formed in the green light-emitting layer, efficiency roll-off can be reduced and regions for exciton formation and recombination can be increased, thereby improving the efficiency and the lifetime.

In some optional embodiments of the present disclosure, a light-emitting unit of the at least two light-emitting units is a green light-emitting unit, and a light-emitting layer in the green light-emitting unit includes a first light-emitting sublayer, a second light-emitting sublayer and a spacer layer disposed between the first light-emitting sublayer and the second light-emitting sublayer.

The first light-emitting sublayer includes a first host material and a first green light doped material, the second light-emitting sublayer includes a second host material and a second green light doped material, and the spacer layer includes a third host material and an optional third green light doped material.

A mass percentage content of the first green light doped material in the first light-emitting sublayer>a mass percentage content of the third green light doped material in the spacer layer, and a mass percentage content of the second green light doped material in the second light-emitting sublayer>the mass percentage content of the third green light doped material in the spacer layer.

In some optional embodiments of the present disclosure, a light extraction layer (CPL, also referred to as a “covering layer”, a “cathode covering layer” or a “capping layer”) is further disposed on a side of the cathode facing away from the light-emitting unit.

In some optional embodiments of the present disclosure, the organic light-emitting element may be prepared by the following method: forming the anode on a transparent or opaque smooth substrate, forming the various organic thin film layers on the anode, and forming the cathode on the organic thin film layers. The organic thin film layer may be formed by using known film forming methods such as evaporation, sputtering, spin coating, impregnation and ion plating.

Embodiments of the present disclosure further provide a display device. The display device includes any one of the organic light-emitting elements provided in the embodiments of the present disclosure.

Since the above organic light-emitting element is used in the display device, the display device also has the technical effects of the organic light-emitting element in the preceding embodiment. It is to be noted that the display device provided in the embodiment of the present disclosure may further include other circuits and elements for supporting a normal operation of the display device.

For example, the display device includes, but is not limited to, any one of a mobile phone, a tablet computer, an electronic photograph frame, an electronic paper and an in-vehicle display device.

For example, several embodiments of the organic light-emitting element (the tandem OLED element) of the present disclosure are listed below. Structures of compounds involved in the following embodiments are as follows:

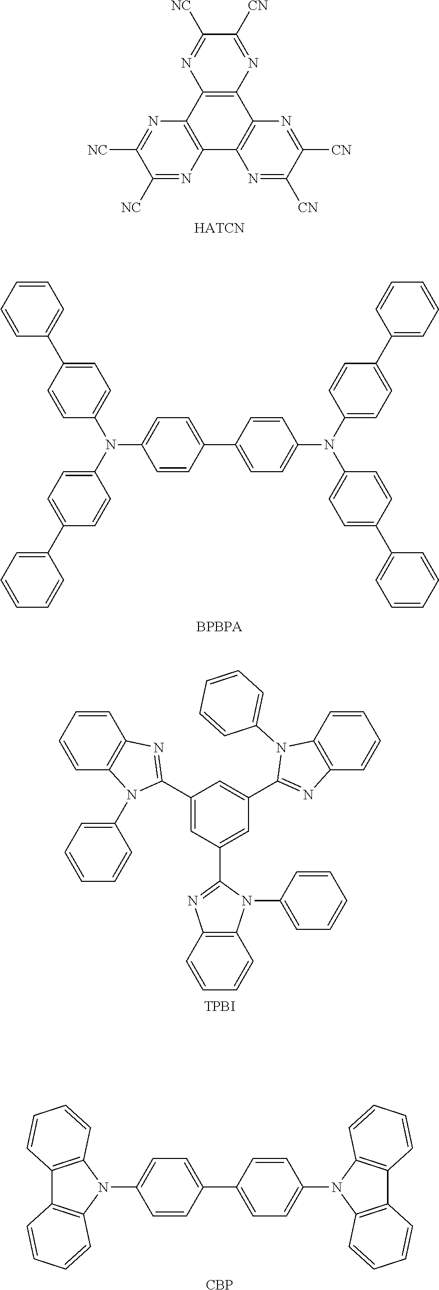

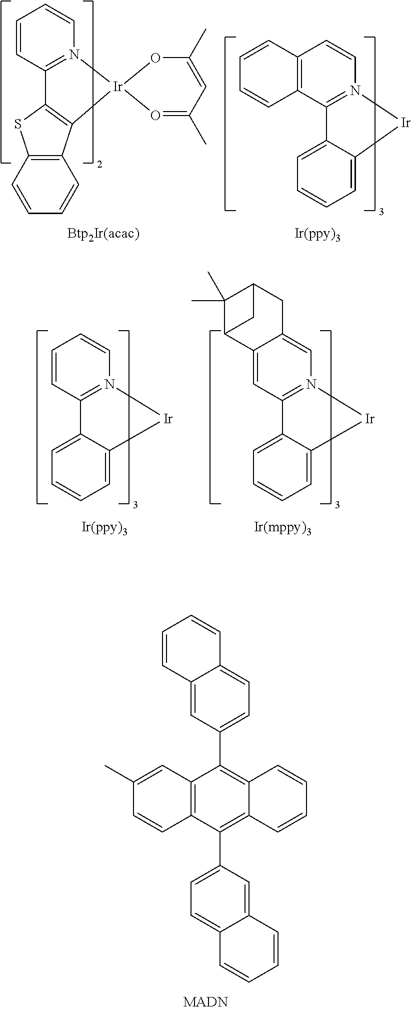

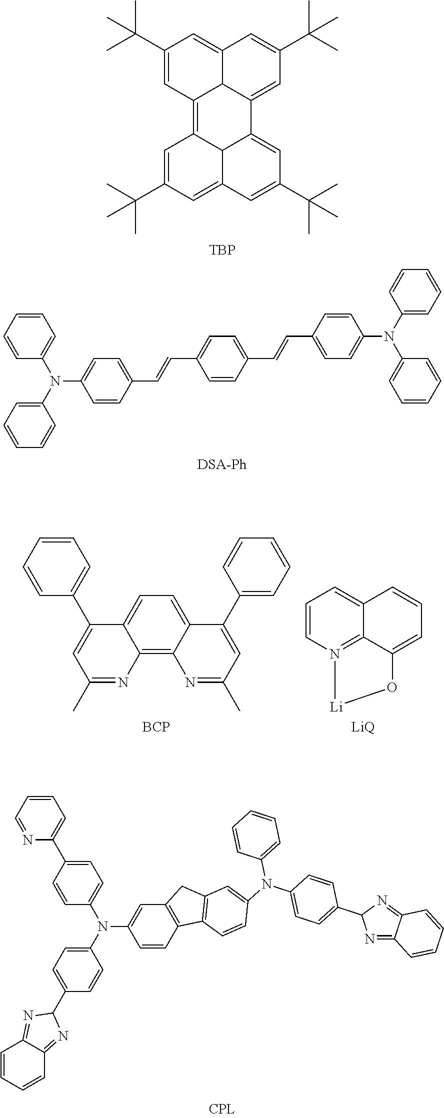

### Example 1

An organic light-emitting element includes an anode, a cathode and two light-emitting units disposed between the anode and the cathode. The organic light-emitting element specifically includes the following structures disposed in sequence: a glass substrate having an ITO anode, a HIL, a first HTL, a first light-emitting layer, a first ETL, a CGL (an n-type layer, a barrier layer and a p-type layer), a second HTL, a second light-emitting layer, a second ETL, an EIL, a cathode (a silver electrode) and a light extraction layer. The second light-emitting layer includes a first light-emitting sublayer, a spacer layer and a second light-emitting sublayer that are disposed in sequence. A method for preparing the organic light-emitting element includes the steps described below.

(1) The glass substrate having the ITO anode was sonicated in isopropanol and deionized water for 30 minutes and cleaned under ozone for 10 minutes. The glass substrate having the ITO anode, which was obtained through magnetron sputtering, was installed onto a vacuum deposition apparatus.

(2) HATCN was deposited by vacuum evaporation on the ITO anode layer at a vacuum degree of 2×10⁻⁶ Pa as the HIL with a thickness of 10 nm.

(3) Compound BPBPA was deposited by vacuum evaporation on the HIL as the first HTL with a thickness of 25 nm.

(4) The first light-emitting layer was deposited by vacuum evaporation on the first HTL. Organic compound CBP was used as a host material, Btp₂Ir(acac) was used as a doped material, a mass ratio of the host material to the doped material was 99:1, and a thickness of the first light-emitting layer was 45 nm.

(5) Compound TPBi was deposited by vacuum evaporation on the first light-emitting layer as the first ETL with a thickness of 10 nm.

(6) The n-type layer was deposited by vacuum evaporation on the first ETL, an n-type host material was BCP, an n-type dopant was Li, a mass ratio of the n-type host material to the n-type dopant was 98:2, and a thickness of the n-type layer was 20 nm.

(7) Compound BCP was deposited by vacuum evaporation on the n-type layer as the barrier layer with a thickness of 1 nm.

(8) The p-type layer was deposited by vacuum evaporation on the barrier layer, a p-type host material was BPBPA, a p-type dopant was HATCN, a mass ratio of the p-type host material to the p-type dopant was 90:10, and a thickness of the p-type layer was 10 nm.

(9) Compound BPBPA was deposited by vacuum evaporation on the p-type layer as the second HTL with a thickness of 90 nm.

(10) The second light-emitting layer (with a total thickness of 45 nm) was deposited by vacuum evaporation on the second HTL, a host material was CBP, and a doped material was Btp₂Ir(acac). The first light-emitting sublayer was deposited, where a mass content of the doped material was 1%, and a thickness of the first light-emitting sublayer was 8 nm. CBP (no doping) was deposited on the first light-emitting sublayer as the spacer layer with a thickness of 7 nm. The second light-emitting sublayer was deposited on the spacer layer, where a mass content of the doped material was 1%, and a thickness of the second light-emitting sublayer was 30 nm.

(11) Compound TPBi was deposited by vacuum evaporation on the second light-emitting layer as the second ETL with a thickness of 30 nm.

(12) LiQ was deposited by vacuum evaporation on the second ETL as the EIL with a thickness of 1 nm.

(13) The Ag electrode was deposited by vacuum evaporation on the EIL as the cathode with a thickness of 10 nm.

(14) Compound CPL was deposited by vacuum evaporation on the cathode as the light extraction layer with a thickness of 70 nm to obtain the organic light-emitting element.

### Example 2

An organic light-emitting element includes the following structures disposed in sequence: a glass substrate having an ITO anode, a HIL, a first HTL, a first light-emitting layer, a first ETL, a CGL (an n-type layer, a barrier layer and a p-type layer), a second HTL, a second light-emitting layer, a second ETL, an EIL, a cathode (a silver electrode) and a light extraction layer. The second light-emitting layer includes a first light-emitting sublayer, a spacer layer and a second light-emitting sublayer that are disposed in sequence. A preparation method includes the steps described below.

(1) The glass substrate having the ITO anode was sonicated in isopropanol and deionized water for 30 minutes and cleaned under ozone for 10 minutes. The glass substrate having the ITO anode, which was obtained through magnetron sputtering, was installed onto a vacuum deposition apparatus.

(2) HATCN was deposited by vacuum evaporation on the ITO anode layer at a vacuum degree of 2×10⁻⁶ Pa as the HIL with a thickness of 10 nm.

(3) Compound BPBPA was deposited by vacuum evaporation on the HIL as the first HTL with a thickness of 25 nm.

(4) The first light-emitting layer was deposited by vacuum evaporation on the first HTL. Organic compound CBP was used as a host material, Ir(ppy)₃ was used as a doped material, a mass ratio of the host material to the doped material was 94:6, and a thickness of the first light-emitting layer was 30 nm.

(5) Compound TPBi was deposited by vacuum evaporation on the first light-emitting layer as the first ETL with a thickness of 10 nm.

(6) The n-type layer was deposited by vacuum evaporation on the first ETL, an n-type host material was BCP, an n-type dopant was Li, a mass ratio of the n-type host material to the n-type dopant was 98:2, and a thickness of the n-type layer was 20 nm.

(7) Compound BCP was deposited by vacuum evaporation on the n-type layer as the barrier layer with a thickness of 1 nm.

(8) The p-type layer was deposited by vacuum evaporation on the barrier layer, a p-type host material was NPB, a p-type dopant was HATCN, a mass ratio of the p-type host material to the p-type dopant was 90:10, and a thickness of the p-type layer was 10 nm.

(9) Compound BPBPA was deposited by vacuum evaporation on the p-type layer as the second HTL with a thickness of 80 nm.

(10) The second light-emitting layer (with a total thickness of 30 nm) was deposited by vacuum evaporation on the second HTL, a host material was CBP, and a doped material was Ir(ppy)₃. The first light-emitting sublayer was deposited, where a mass content of the doped material was 6%, and a thickness of the first light-emitting sublayer was 13 nm. CBP was deposited on the first light-emitting sublayer as the spacer layer (no doping) with a thickness of 4 nm. The second light-emitting sublayer was deposited on the spacer layer, where a mass content of the doped material was 6%, and a thickness of the second light-emitting sublayer was 13 nm.

(11) Compound TPBi was deposited by vacuum evaporation on the second light-emitting layer as the second ETL with a thickness of 30 nm.

(12) LiQ was deposited by vacuum evaporation on the second ETL as the EIL with a thickness of 1 nm.

(13) The Ag electrode was deposited by vacuum evaporation on the EIL as the cathode with a thickness of 10 nm.

(14) Compound CPL was deposited by vacuum evaporation on the cathode as the light extraction layer with a thickness of 70 nm to obtain the organic light-emitting element.

### Example 3

An organic light-emitting element includes the following structures disposed in sequence: a glass substrate having an ITO anode, a HIL, a first HTL, a first light-emitting layer, a first ETL, a CGL (an n-type layer, a barrier layer and a p-type layer), a second HTL, a second light-emitting layer, a second ETL, an EIL, a cathode (a silver electrode) and a light extraction layer. The second light-emitting layer includes a first light-emitting sublayer, a spacer layer and a second light-emitting sublayer that are disposed in sequence. A method for preparing the organic light-emitting element includes the steps described below.

(1) The glass substrate having the ITO anode was sonicated in isopropanol and deionized water for 30 minutes and cleaned under ozone for 10 minutes. The glass substrate having the ITO anode, which was obtained through magnetron sputtering, was installed onto a vacuum deposition apparatus.

(2) HATCN was deposited by vacuum evaporation on the ITO anode layer at a vacuum degree of 2×10⁻⁶ Pa as the HIL with a thickness of 10 nm.

(3) Compound BPBPA was deposited by vacuum evaporation on the HIL as the first HTL with a thickness of 25 nm.

(4) The first light-emitting layer was deposited by vacuum evaporation on the first HTL. Organic compound MADN was used as a host material, TBP was used as a doped material, a mass ratio of the host material to the doped material was 99.5:0.5, and a thickness of the first light-emitting layer was 17 nm.

(5) Compound TPBi was deposited by vacuum evaporation on the first light-emitting layer as the first ETL with a thickness of 10 nm.

(6) The n-type layer was deposited by vacuum evaporation on the first ETL, an n-type host material was BCP, an n-type dopant was Li, a mass ratio of the n-type host material to the n-type dopant was 98:2, and a thickness of the n-type layer was 20 nm.

(7) Compound BCP was deposited by vacuum evaporation on the n-type layer as the barrier layer with a thickness of 1 nm.

(8) The p-type layer was deposited by vacuum evaporation on the barrier layer, a p-type host material was BPBPA, a p-type dopant was HATCN, a mass ratio of the p-type host material to the p-type dopant was 90:10, and a thickness of the p-type layer was 10 nm.

(9) Compound BPBPA was deposited by vacuum evaporation on the p-type layer as the second HTL with a thickness of 50 nm.

(10) The second light-emitting layer (with a total thickness of 17 nm) was deposited by vacuum evaporation on the second HTL, a host material was MADN, and a doped material was TBP. The first light-emitting sublayer was deposited, where a mass content of the doped material was 0.5%, and a thickness of the first light-emitting sublayer was 8 nm. MADN was deposited on the first light-emitting sublayer as the spacer layer (no doping) with a thickness of 1 nm. The second light-emitting sublayer was deposited on the spacer layer, where a mass content of the doped material was 0.5%, and a thickness of the second light-emitting sublayer was 8 nm.

(11) Compound TPBi was deposited by vacuum evaporation on the second light-emitting layer as the second ETL with a thickness of 30 nm.

(12) LiQ was deposited by vacuum evaporation on the second ETL as the EIL with a thickness of 1 nm.

(13) The Ag electrode was deposited by vacuum evaporation on the EIL as the cathode with a thickness of 10 nm.

(14) Compound CPL was deposited by vacuum evaporation on the cathode as the light extraction layer with a thickness of 70 nm to obtain the organic light-emitting element.

### Example 4

An organic light-emitting element includes an anode, a cathode and two light-emitting units disposed between the anode and the cathode. The organic light-emitting element specifically includes the following structures disposed in sequence: a glass substrate having an ITO anode, a HIL, a first HTL, a first light-emitting layer, a first ETL, a CGL (an n-type layer, a barrier layer and a p-type layer), a second HTL, a second light-emitting layer, a second ETL, an EIL, a cathode (a silver electrode) and a light extraction layer. The second light-emitting layer includes a first light-emitting sublayer, a spacer layer and a second light-emitting sublayer that are disposed in sequence. A method for preparing the organic light-emitting element includes the steps described below.

(1) The glass substrate having the ITO anode was sonicated in isopropanol and deionized water for 30 minutes and cleaned under ozone for 10 minutes. The glass substrate having the ITO anode, which was obtained through magnetron sputtering, was installed onto a vacuum deposition apparatus.

(2) HATCN was deposited by vacuum evaporation on the ITO anode layer at a vacuum degree of 2×10⁻⁶ Pa as the HIL with a thickness of 10 nm.

(3) Compound BPBPA was deposited by vacuum evaporation on the HIL as the first HTL with a thickness of 25 nm.

(4) The first light-emitting layer was deposited by vacuum evaporation on the first HTL. Organic compound CBP was used as a host material, Ir(mppy)₃ was used as a doped material, a mass ratio of the host material to the doped material was 88:12, and a thickness of the first light-emitting layer was 35 nm.

(5) Compound TPBi was deposited by vacuum evaporation on the first light-emitting layer as the first ETL with a thickness of 10 nm.

(6) The n-type layer was deposited by vacuum evaporation on the first ETL, an n-type host material was BCP, an n-type dopant was Li, a mass ratio of the n-type host material to the n-type dopant was 98:2, and a thickness of the n-type layer was 20 nm.

(7) Compound BCP was deposited by vacuum evaporation on the n-type layer as the barrier layer with a thickness of 1 nm.

(8) The p-type layer was deposited by vacuum evaporation on the barrier layer, a p-type host material was BPBPA, a p-type dopant was HATCN, a mass ratio of the p-type host material to the p-type dopant was 90:10, and a thickness of the p-type layer was 10 nm.

(9) Compound BPBPA was deposited by vacuum evaporation on the p-type layer as the second HTL with a thickness of 70 nm.

(10) The second light-emitting layer (with a total thickness of 35 nm) was deposited by vacuum evaporation on the second HTL, a host material was CBP, and a doped material was Ir(mppy)₃. The first light-emitting sublayer was deposited, where a mass content of the doped material was 12%, and a thickness of the first light-emitting sublayer was 15 nm. CBP doped with Ir(mppy)₃ having a mass content of 3% was deposited on the first light-emitting sublayer as the spacer layer with a thickness of 5 nm. The second light-emitting sublayer was deposited on the spacer layer, where a mass content of the doped material was 12%, and a thickness of the second light-emitting sublayer was 15 nm.

(11) Compound TPBi was deposited by vacuum evaporation on the second light-emitting layer as the second ETL with a thickness of 30 nm.

(12) LiQ was deposited by vacuum evaporation on the second ETL as the EIL with a thickness of 1 nm.

(13) The Ag electrode was deposited by vacuum evaporation on the EIL as the cathode with a thickness of 10 nm.

(14) Compound CPL was deposited by vacuum evaporation on the cathode as the light extraction layer with a thickness of 70 nm to obtain the organic light-emitting element.

### Example 5

An organic light-emitting element includes the following structures disposed in sequence: a glass substrate having an ITO anode, a HIL, a first HTL, a first light-emitting layer, a first ETL, a CGL (an n-type layer, a barrier layer and a p-type layer), a second HTL, a second light-emitting layer, a second ETL, an EIL, a cathode (a silver electrode) and a light extraction layer. The second light-emitting layer includes a first light-emitting sublayer, a spacer layer and a second light-emitting sublayer that are disposed in sequence. A method for preparing the organic light-emitting element includes the steps described below.

(1) The glass substrate having the ITO anode was sonicated in isopropanol and deionized water for 30 minutes and cleaned under ozone for 10 minutes. The glass substrate having the ITO anode, which was obtained through magnetron sputtering, was installed onto a vacuum deposition apparatus.

(2) HATCN was deposited by vacuum evaporation on the ITO anode layer at a vacuum degree of 2×10⁻⁶ Pa as the HIL with a thickness of 10 nm.

(3) Compound BPBPA was deposited by vacuum evaporation on the HIL as the first HTL with a thickness of 25 nm.

(4) The first light-emitting layer was deposited by vacuum evaporation on the first HTL. Organic compound CBP was used as a host material, Ir(mppy)₃ was used as a doped material, a mass ratio of the host material to the doped material was 90:10, and a thickness of the first light-emitting layer was 40 nm.

(5) Compound TPBi was deposited by vacuum evaporation on the first light-emitting layer as the first ETL with a thickness of 10 nm.

(6) The n-type layer was deposited by vacuum evaporation on the first ETL, an n-type host material was BCP, an n-type dopant was Li, a mass ratio of the n-type host material to the n-type dopant was 98:2, and a thickness of the n-type layer was 20 nm.

(7) Compound BCP was deposited by vacuum evaporation on the n-type layer as the barrier layer with a thickness of 1 nm.

(8) The p-type layer was deposited by vacuum evaporation on the barrier layer, a p-type host material was BPBPA, a p-type dopant was HATCN, a mass ratio of the p-type host material to the p-type dopant was 95:5, and a thickness of the p-type layer was 10 nm.

(9) Compound BPBPA was deposited by vacuum evaporation on the p-type layer as the second HTL with a thickness of 60 nm.

(10) The second light-emitting layer (with a total thickness of 40 nm) was deposited by vacuum evaporation on the second HTL, a host material was CBP, and a doped material was Ir(mppy)₃. The first light-emitting sublayer was deposited, where a mass content of the doped material was 10%, and a thickness of the first light-emitting sublayer was 17.5 nm. The CBP spacer layer (no doping) was deposited on the first light-emitting sublayer with a thickness of 5 nm. The second light-emitting sublayer was deposited on the spacer layer, where a mass content of the doped material was 10%, and a thickness of the second light-emitting sublayer was 17.5 nm.

(11) Compound TPBi was deposited by vacuum evaporation on the second light-emitting layer as the second ETL with a thickness of 30 nm.

(12) LiQ was deposited by vacuum evaporation on the second ETL as the EIL with a thickness of 1 nm.

(13) The Ag electrode was deposited by vacuum evaporation on the EIL as the cathode with a thickness of 10 nm.

(14) Compound CPL was deposited by vacuum evaporation on the cathode as the light extraction layer with a thickness of 70 nm to obtain the organic light-emitting element.

### Example 6

An organic light-emitting element includes the following structures disposed in sequence: a glass substrate having an ITO anode, a HIL, a first HTL, a first light-emitting layer, a first ETL, a CGL (an n-type layer, a barrier layer and a p-type layer), a second HTL, a second light-emitting layer, a second ETL, an EIL, a cathode (a silver electrode) and a light extraction layer. The second light-emitting layer includes a first light-emitting sublayer, a spacer layer and a second light-emitting sublayer that are disposed in sequence. A method for preparing the organic light-emitting element includes the steps described below.

(1) The glass substrate having the ITO anode was sonicated in isopropanol and deionized water for 30 minutes and cleaned under ozone for 10 minutes. The glass substrate having the ITO anode, which was obtained through magnetron sputtering, was installed onto a vacuum deposition apparatus.

(2) HATCN was deposited by vacuum evaporation on the ITO anode layer at a vacuum degree of 2×10⁻⁶ Pa as the HIL with a thickness of 10 nm.

(3) Compound BPBPA was deposited by vacuum evaporation on the HIL as the first HTL with a thickness of 25 nm.

(4) The first light-emitting layer was deposited by vacuum evaporation on the first HTL. Organic compound MADN was used as a host material, DSA-Ph was used as a doped material, a mass ratio of the host material to the doped material was 95:5, and a thickness of the first light-emitting layer was 25 nm.

(5) Compound TPBi was deposited by vacuum evaporation on the first light-emitting layer as the first ETL with a thickness of 10 nm.

(6) The n-type layer was deposited by vacuum evaporation on the first ETL, an n-type host material was BCP, an n-type dopant was Li, a mass ratio of the n-type host material to the n-type dopant was 98:2, and a thickness of the n-type layer was 20 nm.

(7) Compound BCP was deposited by vacuum evaporation on the n-type layer as the barrier layer with a thickness of 1 nm.

(8) The p-type layer was deposited by vacuum evaporation on the barrier layer, a p-type host material was BPBPA, a p-type dopant was HATCN, a mass ratio of the p-type host material to the p-type dopant was 90:10, and a thickness of the p-type layer was 10 nm.

(9) Compound BPBPA was deposited by vacuum evaporation on the p-type layer as the second HTL with a thickness of 50 nm.

(10) The second light-emitting layer (with a total thickness of 25 nm) was deposited by vacuum evaporation on the second HTL, a host material was MADN, and a doped material was DSA-Ph. The first light-emitting sublayer was deposited, where a mass content of the doped material was 5%, and a thickness of the first light-emitting sublayer was 11 nm. MADN doped with DSA-Ph having a mass content of 2% was deposited on the first light-emitting sublayer as the spacer layer with a thickness of 3 nm. The second light-emitting sublayer was deposited on the spacer layer, where a mass content of the doped material was 5%, and a thickness of the second light-emitting sublayer was 11 nm.

(11) Compound TPBi was deposited by vacuum evaporation on the second light-emitting layer as the second ETL with a thickness of 30 nm.

(12) LiQ was deposited by vacuum evaporation on the second ETL as the EIL with a thickness of 1 nm.

(13) The Ag electrode was deposited by vacuum evaporation on the EIL as the cathode with a thickness of 10 nm.

(14) Compound CPL was deposited by vacuum evaporation on the cathode as the light extraction layer with a thickness of 70 nm to obtain the organic light-emitting element.

### Comparative Example 1

An organic light-emitting element differs from that in Example 1 only in that no spacer layer was disposed in the second light-emitting layer. That is, in the second light-emitting layer, CBP was used as the host material, Btp₂Ir(acac) was used as the doped material, the mass content of the doped material was 1%, and the evaporation thickness of the second light-emitting layer was 45 nm. Other layers, thicknesses, materials and preparation methods were the same as those in Example 1.

### Comparative Example 2

An organic light-emitting element differs from that in Example 2 only in that no spacer layer was disposed in the second light-emitting layer. That is, in the second light-emitting layer, CBP was used as the host material, Ir(ppy)₃ was used as the doped material, the mass content of the doped material was 6%, and the evaporation thickness of the second light-emitting layer was 30 nm. Other layers, thicknesses, materials and preparation methods were the same as those in Example 2.

### Comparative Example 3

An organic light-emitting element differs from that in Example 3 only in that no spacer layer was disposed in the second light-emitting layer. That is, in the second light-emitting layer, MADN was used as the host material, TBP was used as the doped material, the mass content of the doped material was 0.5%, and the evaporation thickness of the second light-emitting layer was 17 nm. Other layers, thicknesses, materials and preparation methods were the same as those in Example 3.

### Performance Evaluation of OLED Elements

Currents of the OLED element at different voltages were tested by the Keithley 2365A digital nanovoltmeter, and then current densities of the OLED element at different voltages were obtained by dividing each current by the light-emitting area. The brightness and radiation energy flux densities of the OLED element at different voltages were tested by the Konicaminolta CS-2000 spectroradiometer. According to the current densities and brightness of the OLED element at different voltages, the working voltage (V) and current efficiency (cd/A) of the OLED element at the same current density (10 mA/cm²) were obtained. A lifetime T95 (under a testing condition of 50 mA/cm²) was obtained by measuring time when the brightness of the OLED element reached 95% of its initial brightness. Test data is shown in Table 1.

TABLE 1

| | Voltage | Current Efficiency | Lifetime | Light |
|---|---|---|---|---|
| | (V) | (cd/A) | (h) | Color |
| Example 1 | 5.7 | 16.1 | 81 | red |
| Example 2 | 6.5 | 33.4 | 53 | green light |
| Example 3 | 7.4 | 3.6 | 42 | blue light |
| Example 4 | 7.0 | 29.2 | 96 | green light |
| Example 5 | 7.5 | 31.3 | 88 | green light |
| Example 6 | 7.9 | 11.6 | 41 | blue light |
| Comparative | 6.0 | 14.4 | 58 | red |
| Example 1 | | | | |
| Comparative | 6.8 | 30.7 | 35 | green light |
| Example 2 | | | | |
| Comparative | 7.6 | 3.0 | 34 | blue light |
| Example 3 | | | | |

According to the test data in Table 1, in the organic light-emitting element provided in the present disclosure, the element has a relatively low working voltage, relatively high luminescence efficiency and a relatively long lifetime derived from the special design of doping concentration gradient in the light-emitting layer.

Compared with Examples 1 to 3, conventional uniform doping concentrations are used in the light-emitting layers in Comparative Examples 1 to 3, resulting in relatively short element lifetimes, relatively low efficiencies, high drive voltages and overall performance poorer than that in Examples 1 to 3.

The applicant has stated that although the organic light-emitting element and the display device including the same of the present disclosure are described through the embodiments described above, the present disclosure is not limited to the process steps described above, which means that the implementation of the present disclosure does not necessarily depend on the process steps described above. It should be apparent to those skilled in the art that any improvements made to the present disclosure, equivalent replacements of raw materials selected in the present disclosure, additions of adjuvant ingredients, and selections of specific methods, etc., all fall within the protection scope and the disclosed scope of the present disclosure.

What is claimed is:

1. An organic light-emitting element, comprising an anode, a cathode and at least two light-emitting units disposed between the anode and the cathode, wherein each of the at least two light-emitting units independently comprises a light-emitting layer;
at least one light-emitting layer comprises a first light-emitting sublayer, a second light-emitting sublayer and a spacer layer disposed between the first light-emitting sublayer and the second light-emitting sublayer;
the first light-emitting sublayer comprises a first host material and a first doped material, the second light-emitting sublayer comprises a second host material and a second doped material, and the spacer layer comprises a third host material and an optional third doped material; and
a mass percentage content of the first doped material in the first light-emitting sublayer>a mass percentage content of the third doped material in the spacer layer, and a mass percentage content of the second doped material in the second light-emitting sublayer>the mass percentage content of the third doped material in the spacer layer.

2. The organic light-emitting element according to claim 1, wherein the mass percentage content of the first doped material in the first light-emitting sublayer is 0.5% to 12%, and/or the mass percentage content of the second doped material in the second light-emitting sublayer is 0.5% to 12%, and/or the mass percentage content of the third doped material in the spacer layer is less than or equal to 3%.

3. The organic light-emitting element according to claim 2, wherein the first doped material, the second doped material and the third doped material are phosphorescent doping materials, the mass percentage content of the first doped material in the first light-emitting sublayer is 1% to 12%, and/or the mass percentage content of the second doped material in the second light-emitting sublayer is 1% to 12%, and/or the mass percentage content of the third doped material in the spacer layer is less than or equal to 3%.

4. The organic light-emitting element according to claim 1, wherein the first doped material, the second doped material and the third doped material are fluorescent doping materials, the mass percentage content of the first doped material in the first light-emitting sublayer is 0.5% to 5%, and/or the mass percentage content of the second doped material in the second light-emitting sublayer is 0.5% to 5%, and/or the mass percentage content of the third doped material in the spacer layer is less than or equal to 2%.

5. The organic light-emitting element according to claim 1, wherein thicknesses of the first light-emitting sublayer and the second light-emitting sublayer are each independently 8 nm to 30 nm, and/or a thickness of the spacer layer is 1 nm to 7 nm.

6. The organic light-emitting element according to claim 1, wherein the first host material, the second host material and the third host material each independently comprise any one or a combination of at least two of an electron-type host material, a hole-type host material, a bipolar host material and an exciplex material.

7. The organic light-emitting element according to claim 1, wherein each of the at least two light-emitting units independently comprises a hole transport zone and an electron transport zone, and the light-emitting layer is disposed between the hole transport zone and the electron transport zone.

8. The organic light-emitting element according to claim 7, wherein the hole transport zone comprises a hole transport layer (HTL) and an optional electron blocking layer (EBL); and/or
the electron transport zone comprises an electron transport layer (ETL) and an optional hole blocking layer (HBL); and/or
a hole injection layer (HIL) is further disposed between the anode and a light-emitting unit adjacent to the anode, and/or an electron injection layer (EIL) is further disposed between the cathode and a light-emitting unit adjacent to the cathode; and/or
a charge generation layer (CGL) is disposed between any two adjacent light-emitting units.

9. The organic light-emitting element according to claim 8, wherein the CGL comprises a p-type layer, an n-type layer and a barrier layer disposed between the p-type layer and the n-type layer.

10. The organic light-emitting element according to claim 9, wherein the p-type layer comprises a p-type host material and a p-type dopant, the n-type layer comprises an n-type host material and an n-type dopant, and the barrier layer comprises a p-type host material and/or an n-type host material.

11. The organic light-emitting element according to claim 9, wherein the barrier layer has a lowest unoccupied molecular orbital (LUMO) energy level of 2.5-2.9 eV, and a highest occupied molecular orbital (HOMO) energy level of 5.5-6.0 cV.

12. The organic light-emitting element according to claim 9, wherein thicknesses of the p-type layer and the n-type layer are each independently 2 nm to 30 nm, and/or a thickness of the barrier layer is 0.5 nm to 2 nm.

13. The organic light-emitting element according to claim 1, wherein each of the at least two light-emitting units is independently selected from any one of a green light-emitting unit, a blue light-emitting unit, a red light-emitting unit or a yellow light-emitting unit.

14. The organic light-emitting element according to claim 1, wherein a light-emitting unit of the at least two light-emitting units is a green light-emitting unit, and a light-emitting layer in the green light-emitting unit comprises a first light-emitting sublayer, a second light-emitting sublayer and a spacer layer disposed between the first light-emitting sublayer and the second light-emitting sublayer;
the first light-emitting sublayer comprises a first host material and a first green light doped material, the second light-emitting sublayer comprises a second host material and a second green light doped material, and the spacer layer comprises a third host material and an optional third green light doped material; and
a mass percentage content of the first green light doped material in the first light-emitting sublayer>a mass percentage content of the third green light doped material in the spacer layer, and a mass percentage content of the second green light doped material in the second light-emitting sublayer>the mass percentage content of the third green light doped material in the spacer layer.

15. The organic light-emitting element according to claim 1, wherein a light extraction layer is further disposed on a side of the cathode facing away from the at least two light-emitting units.

16. A display device, comprising the organic light-emitting element according to claim 1.
